(19) United States
(12) Patent Application Publication
(10) Pub. No.: US 2014/0273519 A1
(43) Pub. Date: Sep. 18, 2014

(54) HYDROGEN-PLASMA PROCESS FOR SURFACE PREPARATION PRIOR TO INSULATOR DEPOSITION ON COMPOUND SEMICONDUCTOR MATERIALS

(71) Applicants: Sharka M. Prokes, Columbia, MD (US); Erin Cleveland, College Park, MD (US); Laura Ruppalt, Alexandria, VA (US)

(72) Inventors: Sharka M. Prokes, Columbia, MD (US); Erin Cleveland, College Park, MD (US); Laura Ruppalt, Alexandria, VA (US)

(21) Appl. No.: 14/192,935

(22) Filed: Feb. 28, 2014

Related U.S. Application Data
(60) Provisional application No. 61/778,561, filed on Mar. 13, 2013.

(51) Int. Cl. H01L 21/02

(52) U.S. Cl. CPC H01L 21/02315; H01L 21/0226
USPC 438/778

(57) ABSTRACT

A method of making a semiconductor material by pretreating a semiconductor substrate having a native oxide on the substrate surface under vacuum with hydrogen plasma to remove and/or modify the native oxide. After plasma exposure, a high-k dielectric is deposited in-situ onto the substrate using atomic layer deposition. There is no break in the vacuum between the plasma exposure and the atomic layer deposition. Also disclosed is the related semiconductor/dielectric material stack.

### PRIORITY CLAIM

The present application is a non-provisional application claiming the benefit of U.S. Provisional Application No. 61/778,561, filed on Mar. 13, 2013 by Sharka M. Prokes et al., entitled “Hydrogen-Plasma Process for Surface Preparation Prior to Insulator Deposition on Compound Semiconductor Materials,” the entire contents of which is incorporated herein by reference.

### BACKGROUND OF THE INVENTION

1. Field of the Invention

The present invention relates generally to semiconductor materials and, more specifically, to hydrogen plasma pre-treatment of semiconductor materials.

2. Description of the Prior Art

Currently, many analog and nearly all digital electronics are fabricated from silicon-based materials. However, due to their superior electronic properties, compound semiconductors, such as GaSb, show promise as alternative materials for high-speed, high-performance electronic devices. In addition, the III-V compound semiconductors generally have direct energy bandgaps, which make them also useful for opto-electronic devices such as light-emitting diodes (LEDs), lasers, and photodetectors.

Many semiconductor-based electronic and optoelectronic devices require the integration of dielectric layers to enhance charge control, reduce leakage or sidewall currents, and improve overall device performance. In addition to providing insulating properties, the dielectric layer also must form a low-defect interface with the semiconductor to support device performance. In silicon, the native oxide, SiO₂, has proven an effective material for achieving insulating properties with a low-defect interface. However, the native oxides of most compound semiconductors are complex in composition and structure and form highly-defected interfaces that prevent optimal device operation.

Integration of alternative dielectrics on compound semiconductors has been demonstrated using a variety of deposition techniques, including Atomic layer Deposition (ALD) and Chemical Vapor Deposition (CVD). However, to achieve a low-defect interface, the surface of the semiconductor must be treated prior to insulator deposition to remove or modify the native oxides that naturally form.

III-V compound semiconductors are attracting widespread attention as an alternative material to Si in advanced complementary metal-oxide-semiconductor (CMOS) applications; their high electron and hole mobilities, as well as relatively narrow bandgaps make them increasingly attractive for high-speed, low power applications. A significant amount of work already exists on n-channel III-V metal-oxide-semiconductor field-effect transistors (MOSFETs) demonstrating excellent electron mobility and high drive currents. However, hole mobility in III-V p-channel MOSFETs typically lags in comparison to Si. Among the III-V semiconductors, GaSb is a promising material for both n- and p-channel devices due to its high electron and hole mobilities (bulk mobility˜6000 cm²/Vs and 850 cm²/Vs, respectively), which are found to be amongst the highest of the III-V semiconductor materials. However, the poor quality of the gate oxide/GaSb interface has limited the use of GaSb in microelectronics. Unlike the silicon-silicon dioxide interface pair, the native oxide found on GaSb is complex in structure and composition, forming heavily defected interfaces that pin the semiconductor Fermi-level near midgap and limit the device's ability to modulate charge.

The increasing need to integrate high-k dielectric thin films into CMOS structures has led researchers to turn to ALD for insulator growth. ALD is a gas phase deposition technique that utilizes self-limiting chemistries to produce thin solid films with excellent atomic-level thickness control. ALD is widely accepted as a means to produce high quality films over large surface areas with excellent uniformity and conformality. These attributes are inherent to the self-limiting nature of the ALD surface reactions: alternating reactant exposures of two gaseous precursors create a saturated chemisorbed surface which leads to film growth one sub-monolayer at a time. The sequential behavior of the precursor exposures helps avoid the formation of gas-phase particles and creates thin, continuous, pin-hole-free films that are critical to the operation of CMOS devices. Therefore, particular attention should be focused on the development of techniques to form low-defect interfaces between III-V surfaces and high-k films deposited by ALD.

Up to this point, the complex native oxide removal has been performed by ex-situ wet chemical etches prior to the deposition of high-k dielectric. Aqueous oxide removal treatments reported in conjunction with ALD include: HCl, (NH₄)₂S, NH₄OH, and HF. Although some of these chemical etches have been reported to be effective at removing the native oxide and unpinning the semiconductor Fermi-level in fabricated devices, the most serious drawback is that the surface chemistry is extremely difficult to control and thus the repeatability of the treatments is difficult. Furthermore, since these chemical etching treatments are done ex-situ, further oxidation can occur prior to the growth of the high-k dielectric layer, resulting again in Fermi level pinning at the interface and unacceptable device performance. Pre-insulator-deposition plasma-based treatments have not been previously applied to the technologically relevant Sb-based or SiC compound semiconductors.

GaSb is known to have a highly reactive surface. On exposure to air it will form a complex native oxide composed of not only Sb-oxides and Ga-oxides, but elemental Sb as well. Therefore, a significant effort has been focused on surface preparations prior to ALD that remove native oxides and passivate GaSb atoms to ensure the best possible interface. Current approaches for oxide removal primarily consist of wet etches, such as HCl, HF, (NH₄)₂S, and NH₄OH; however, due to the rapid re-oxidation of the GaSb after oxide removal and a general lack of reproducibility, a better means of interface cleaning is desirable. Recent progress in the field of ALD on III-Vs has led researchers to a proposed “self-cleaning” mechanism through the use of the ALD precursor trimethylaluminum (TMA), in which the native oxides are consumed during the initial TMA half-cycle. While effective, this process has not been proven to be standalone for oxide removal, as it is typically preceded by a wet chemical etch that removes the bulk of the native oxide. Alternatively, hydrogen (H₂) plasma cleaning has been considered a potential candidate for efficient low temperature oxide removal from III-V semiconductors during molecular beam epitaxy (MBE) regrowth processes. Under appropriate conditions, it has been shown that H₂-plasma treatments in ultra-high vacuum can result in high quality, defect-, impurity-, and oxide-free GaSb surfaces.

### BRIEF SUMMARY OF THE INVENTION

The aforementioned problems are overcome in the present invention which provides a method of making a semiconductor/dielectric material by pretreating a semiconductor substrate having a native oxide on the substrate surface under vacuum with hydrogen plasma to remove and/or modify the native oxide. After plasma exposure, a high-k dielectric is deposited in-situ onto the substrate using atomic layer deposition. There is no break in the vacuum between the plasma exposure and the atomic layer deposition. Also disclosed is the related semiconductor material.

This invention is for an in-situ hydrogen plasma treatment of semiconductor material surfaces that contain complex native oxides. With this hydrogen plasma treatment followed in-situ by high-k dielectric material deposition by Atomic Layer Deposition (ALD), most of these native oxides are eliminated or modified leading to a high quality electrical interface with low interfacial defect densities.

One advantage of this surface oxide removal and modification technique is that all pre-treatment is done in situ, immediately prior to dielectric deposition, reducing the likelihood of contamination or reoxidation of surface possible with ex situ methods. Furthermore, highly defective native oxides are removed via clean and controlled indirect hydrogen plasma treatment. This hydrogen-plasma pretreatment approach avoids wet-chemical etches, which are subject to incidental contamination and lack of reproducibility. Additionally, MOS capacitors fabricated exhibit excellent charge modulation and decreased frequency dispersion of accumulation capacitance, indicating a reduction in undesired states at the dielectric/semiconductor boundary and an improvement in the electrical interface. Reduction in interface trap states on GaSb surfaces achieved with hydrogen plasma treatment are comparable, if not better than, other approaches. Moreover, comparable results can be achieved by tuning any one of multiple plasma parameters (power, exposure time, substrate temperature), allowing greater flexibility to accommodate substrate or instrumentation constraints.

These and other features and advantages of the invention, as well as the invention itself, will become better understood by reference to the following detailed description, appended claims, and accompanying drawings.

### BRIEF DESCRIPTION OF THE DRAWINGS

FIG. 1 shows Sb 3d and Ga 3d core-level XPS spectra for (a) the untreated 500 nm thick GaSb epilayer with native oxide and after exposure to an H₂ plasma for 10 minutes with varying plasma powers of (b) 25 W, (c) 50 W, (d) 75 W, and (e) 100 W. Following plasma exposure, samples (b)-(e) were coated with TMA.

FIG. 2 shows frequency-resolved C-V measurements for GaSb MOS capacitors fabricated on (a) an untreated GaSb substrate and on substrates exposed to H₂ plasma pretreatments using best case plasma parameters: (b) 100 W, 10 min, 150° C., (c) 50 W, 10 min, 250° C., and (d) 50 W, 20 min, 150° C.

### DETAILED DESCRIPTION OF THE INVENTION

In the present invention, semiconductor substrates are loaded into an atomic layer deposition (ALD) reactor. The samples are exposed to a hydrogen plasma that acts to remove and/or modify any native oxide present on the surface. The effectiveness of the removal and modification of the native oxide layer can be tuned by varying the substrate temperature, hydrogen plasma power, and/or hydrogen plasma exposure time. Following plasma exposure, high-k dielectric deposition is accomplished via a standard ALD process without breaking vacuum and without exposing the sample to the atmosphere.

Semiconductor substrates are loaded into an atomic layer deposition (ALD) vacuum system equipped with a hydrogen plasma source. Once under vacuum, substrates are heated to the desired processing temperature, typically 150° C. to 300° C., which is less than the native oxide desorption temperature. After the base substrate temperature is reached, the samples are exposed to a hydrogen plasma that acts to remove and/or modify any native oxide present on the surface. The effectiveness of the removal and modification of the native oxide layer can be tuned by varying the substrate temperature (between 150° C. and 300° C., hydrogen plasma power (25W to 150W), and/or hydrogen plasma exposure time (1 minute to 120 minutes). Following plasma exposure, high-k dielectric deposition is accomplished via a standard ALD process without breaking vacuum and without exposing the sample to atmosphere. Alternatively, if atmospheric exposure is required, a single passivating monolayer of metallic ALD precursor can be deposited onto the treated semiconductor surface prior to breaking vacuum. This passivating layer serves to protect the surface from incidental atmospheric oxidation.

Chemical modification and removal of the surface native oxide were confirmed via X-ray photo-electron spectroscopy (XPS) (FIG. 1). Under appropriate treatment conditions (substrate temperature, hydrogen plasma power, and plasma exposure time), the hydrogen plasma exposure results in the removal of native sub-oxides and a transformation of the complex native oxide to a more compositionally-pure interlayer. Comparable modifications are not seen when using the conventional wet-etch (HCl-treatment) approach.

The electrical quality of the semiconductor-dielectric interface was probed using frequency-varying capacitance-voltage (C-V) measurements on metal-oxide-semiconductor capacitors (MOScaps) fabricated on material stacks subjected to the in-situ hydrogen plasma treatment and subsequent high-k dielectric deposition. Electrical data verified that the transformed interlayer resulting from hydrogen plasma exposure leads to significantly improved charge modulation (indicated by increased capacitance modulation) at the semiconductor/dielectric interface and a corresponding reduction of interface trap states (FIG. 2).

The in situ hydrogen plasma treatment is applicable to a wide range of semiconductors possessing complex native oxides, in particular those arising on compound semiconductor surfaces (including but not limited to GaSb, InAs, SiC, etc.). Additional surface treatments completed prior to hydrogen plasma exposure, for example epilayer growth, solvent cleans, and aqueous chemical treatments, may be necessary to achieve optimal interface properties and device performance.

The above descriptions are those of the preferred embodiments of the invention. Various modifications and variations are possible in light of the above teachings without departing from the spirit and broader aspects of the invention. It is therefore to be understood that the claimed invention may be practiced otherwise than as specifically described. Any references to claim elements in the singular, for example, using the articles “a,” “an,” “the,” or “said,” is not to be construed as limiting the element to the singular.

What is claimed as new and desired to be protected by Letters Patent of the United States is:

1. A method of forming a semiconductor/dielectric material, comprising:
loading a semiconductor substrate into an atomic layer deposition reactor and applying a vacuum, wherein the substrate may contain a native oxide on a surface of the substrate;
exposing the substrate to a hydrogen plasma, wherein the hydrogen plasma removes, modifies, or removes and modifies the native oxide; and
after plasma exposure, in-situ depositing a high-k dielectric onto the substrate using atomic layer deposition, wherein there is no break in the vacuum between the plasma exposure and the atomic layer deposition.

2. The method of claim 1, wherein the removal, modification, or removal and modification of the native oxide is optimized by varying the substrate temperature, the hydrogen plasma power, the hydrogen plasma exposure time, or any combination thereof.

3. The method of claim 1, wherein during the plasma exposure, the substrate temperature is between 150° C. and 300° C.

4. The method of claim 1, wherein the hydrogen plasma power is between 25 W and 150 W.

5. The method of claim 1, wherein the hydrogen plasma exposure time is between 1 minute and 120 minutes.

6. The method of claim 1, wherein the in-situ deposition of the high-k dielectric is done without exposing the substrate to the atmosphere.

7. The method of claim 1, wherein the substrate comprises GaSb, InAs, or SiC.

8. The method of claim 1, wherein the substrate comprises a III-V compound semiconductor material.

9. A semiconductor/dielectric material formed by the method, comprising:
loading a semiconductor substrate into an atomic layer deposition reactor and applying a vacuum, wherein the substrate may contain a native oxide on a surface of the substrate;
exposing the substrate to a hydrogen plasma, wherein the hydrogen plasma removes, modifies, or removes and modifies the native oxide; and
after plasma exposure, in-situ depositing a high-k dielectric onto the substrate using atomic layer deposition, wherein there is no break in the vacuum between the plasma exposure and the atomic layer deposition.

10. The semiconductor material of claim 9, wherein the removal, modification, or removal and modification of the native oxide is optimized by varying the substrate temperature, the hydrogen plasma power, the hydrogen plasma exposure time, or any combination thereof.

11. The semiconductor material of claim 9, wherein during the plasma exposure, the substrate temperature is between 150° C. and 300° C.

12. The semiconductor material of claim 9, wherein the hydrogen plasma power is between 25 W and 150 W.

13. The semiconductor material of claim 9, wherein the hydrogen plasma exposure time is between 1 minute and 120 minutes.

14. The semiconductor material of claim 9, wherein the in-situ deposition of the high-k dielectric is done without exposing the substrate to the atmosphere.

15. The semiconductor material of claim 9, wherein the substrate comprises GaSb, InAs, or SiC.

16. The semiconductor material of claim 9, wherein the substrate comprises a III-V compound semiconductor material.
